(19) United States
(12) Patent Application Publication
(10) Pub. No.: US 2026/0324487 A1
(43) Pub. Date: Oct. 15, 2026

(54) THERMOSETTING ADHESIVE COMPOSITION, ULTRAVIOLET-IRRADIATED PRODUCT OF SAME, LAMINATED FILM, AND METHOD FOR PRODUCING CONNECTION BODY

(71) Applicant: Resonac Corporation, Tokyo (JP)

(72) Inventors: Yohsuke KOSUGA, Tokyo (JP); Masanori NATSUKAWA, Tokyo (JP); Takuya HAYASAKA, Tokyo (JP)

(73) Assignee: Resonac Corporation, Tokyo (JP)

(21) Appl. No.: 19/476,421

(22) PCT Filed: Sep. 19, 2024
(86) PCT No.: PCT/JP2024/033538

§ 371 Date: Oct. 17, 2025

(30) Foreign Application Priority Data
Sep. 20, 2023 (JP) 2023-152158

(51) Int. Cl. H10W 72/30; C09J 5/06; C09J 163/00; H05K 1/14; H05K 1/181; H05K 3/32; H05K 3/36; H10W 72/00; H10W 90/00

(52) U.S. Cl. CPC H10W 72/354; C09J 5/06; C09J 163/00; H05K 1/147; H05K 1/181; H05K 3/32; H05K 3/361; H10W 72/01365; H10W 72/07341; H10W 72/07502; H10W 90/731; H10W 90/751; C09J 2203/326; C09J 2301/408; C09J 2301/416; C09J 2463/00; H05K 2201/0129; H05K 2201/0209; H05K 2201/041; H05K 2201/10151; H05K 2201/10287; H05K 2203/049

(57) ABSTRACT

A thermosetting adhesive composition is disclosed which contains a thermosetting resin, a thermoplastic resin, an inorganic filler, and a photocleavable compound that cleaves upon irradiation with ultraviolet rays to generate an amine compound. The thermosetting resin is a resin that cures by being heated in the presence of the amine compound. After being irradiated with ultraviolet rays under conditions of an illuminance of 80 mW/cm² and an integrated light quantity of 600 mJ/cm², the shear viscosity at 75° C. is from 100 to 6,000 Pa·s. After being irradiated with ultraviolet rays under conditions of an illuminance of 80 mW/cm² and an integrated light quantity of 600 mJ/cm² and further heated at 75° C. for 3 hours, the storage modulus at 35° C. is from 100 to 4,000 MPa.

### TECHNICAL FIELD

The present disclosure relates to a thermosetting adhesive composition, an ultraviolet-irradiated product of the same, a laminated film, a connection body, and a method for producing the same.

### BACKGROUND ART

Conventionally, a semiconductor device is manufactured through the following steps. First, a semiconductor wafer is singulated into semiconductor chips by performing a dicing step with the semiconductor wafer attached to a dicing pressure-sensitive adhesive sheet. Thereafter, a pickup step, a die bonding step, a wire bonding step, a molding step, and the like are performed. Patent Literature 1 discloses an adhesive sheet with both pressure-sensitive and thermosetting properties (die-bond dicing sheet) that has both a function of fixing a semiconductor wafer in a dicing step and a function of adhering a semiconductor chip to a substrate in a die bonding step. Patent Literature 2 discloses an adhesive sheet with both pressure-sensitive and thermosetting properties that acts as a dicing tape in a dicing step, has excellent connection reliability in joining a semiconductor element and a support member, and maintains sufficient fluidity after a thermal history of wire bonding.

### CITATION LIST

### Patent Literature

Patent Literature 1: JP 2007-288170 A
Patent Literature 2: JP 2009-209345 A

### SUMMARY OF INVENTION

### Technical Problem

By the way, in recent years, with the evolution of semiconductor modules for small devices represented by smartphones, the manufacturing process of semiconductor modules has also changed significantly from conventional ones. For example, the practical application of processes that do not include a dicing step and a die bonding step is being promoted. Along with this, thermosetting adhesive compositions used in the manufacturing process of semiconductor modules are also required to have different performance from conventional ones. In addition to such circumstances, the present inventors, assuming that materials with relatively low heat resistance are used for semiconductor modules, have proceeded with the development of a thermosetting adhesive composition in which the curing reaction proceeds sufficiently under low-temperature conditions of 85° C. or lower. When improvements were made based on a conventional thermosetting adhesive composition with excellent low-temperature curability, although the development target for low-temperature curability was achieved, it was found that when a die bonding step was performed using a film-form adhesive made of the thermosetting adhesive composition, voids may occur at the interface between the film-form adhesive and a member. Since the occurrence of voids at the interface between the film-form adhesive and the member may cause a decrease in adhesive strength, it is required to suppress the occurrence of voids.

A main object of the present disclosure is to provide a thermosetting adhesive composition that can suppress the occurrence of voids at the interface between a film-form adhesive and a member when a die bonding step is performed using the film-form adhesive made of the thermosetting adhesive composition.

### Solution to Problem

The present inventors, in order to solve the above problem, have studied a thermosetting adhesive composition, focusing mainly on the shear viscosity at 75° C., which can be the thermocompression bonding temperature, and have found that when the shear viscosity at 75° C. is within a predetermined range and the storage modulus after curing at 35° C. is within a predetermined range, the occurrence of voids can be suppressed in the die bonding step, thereby completing the invention of the present disclosure.

The present disclosure provides the thermosetting adhesive compositions described in [1] to [7], the ultraviolet-irradiated product of the thermosetting adhesive composition described in [8], the laminated film described in [9], the methods for producing a connection body described in [10] to [13], and the connection bodies described in [14] and [15].

[1] A thermosetting adhesive composition containing: a thermosetting resin; a thermoplastic resin; an inorganic filler; and a photocleavable compound that cleaves upon irradiation with ultraviolet rays to generate an amine compound, wherein the thermosetting resin is a resin that cures by being heated in the presence of the amine compound, after the thermosetting adhesive composition is irradiated with ultraviolet rays under conditions of an illuminance of 80 mW/cm² and an integrated light quantity of 600 mJ/cm², a shear viscosity of the thermosetting adhesive composition at 75° C. is from 100 to 6,000 Pa·s, and after the thermosetting adhesive composition is irradiated with ultraviolet rays under conditions of an illuminance of 80 mW/cm² and an integrated light quantity of 600 mJ/cm² and further heated at 75° C. for 3 hours, a storage modulus of the thermosetting adhesive composition at 35° C. is from 100 to 4,000 MPa.

[2] The thermosetting adhesive composition according to [1], wherein after the thermosetting adhesive composition is irradiated with ultraviolet rays under conditions of an illuminance of 80 mW/cm² and an integrated light quantity of 600 mJ/cm² and further heated at 75° C. for 3 hours, a storage modulus of the thermosetting adhesive composition at 75° C. is 10 MPa or more.

[3] The thermosetting adhesive composition according to [1] or [2], wherein a content of the thermoplastic resin is from 5 to 35% by mass, based on a total amount of the thermosetting adhesive composition.

[4] The thermosetting adhesive composition according to any one of [1] to [3], wherein a content of the inorganic filler is 45% by mass or less, based on a total amount of the thermosetting adhesive composition.

[5] The thermosetting adhesive composition according to any one of [1] to [4], wherein the photocleavable compound is a compound having an α-aminoacetophenone skeleton.

[6] The thermosetting adhesive composition according to any one of [1] to [5], wherein a reaction rate calculated by substituting a calorific value C1 and a calorific value C2, which are respectively obtained from a DSC curve obtained by differential scanning calorimetry at a heating rate of 10° C./min in a temperature range of 50 to 200° C., into the following formula is 45% or more:

Reaction rate (%)=(C1−C2)/C1×100
where C1 represents the calorific value for which a measurement target is a resin composition after the thermosetting adhesive composition has been irradiated with ultraviolet rays under conditions of an illuminance of 80 mW/cm² and an integrated light quantity of 600 mJ/cm², and
C2 represents the calorific value, for which a measurement target is a resin composition after the thermosetting adhesive composition has been irradiated with ultraviolet rays under conditions of an illuminance of 80 mW/cm² and an integrated light quantity of 600 mJ/cm² and further heated at 75° C. for 3 hours.

[7] The thermosetting adhesive composition according to any one of [1] to [6], wherein a glass transition temperature of the thermoplastic resin is from −50 to 20° C.

[8] An ultraviolet-irradiated product of a thermosetting adhesive composition, obtained by irradiating the thermosetting adhesive composition according to any one of [1] to [7] with ultraviolet rays, wherein the product containing: the thermosetting resin; the thermoplastic resin; the inorganic filler; and the amine compound, a shear viscosity of the ultraviolet-irradiated product at 75° C. is from 100 to 6,000 Pa·s, and after being heated at 75° C. for 3 hours, a storage modulus of the ultraviolet-irradiated product at 35° C. is from 100 to 4,000 MPa.

[9] A laminated film including: a base film; and an adhesive layer provided on a surface of the base film, wherein the adhesive layer is formed of the thermosetting adhesive composition according to any one of [1] to [7].

[10] A method for producing a connection body, the method including, in this order: (A) providing a laminate including a first circuit member, a second circuit member, and an adhesive layer disposed between the first circuit member and the second circuit member; (B) heating the laminate at 65 to 85° C. for 30 to 240 minutes; and (C) wire bonding the first circuit member and the second circuit member, wherein the adhesive layer is formed of the thermosetting adhesive composition according to any one of [1] to [7], and the method further includes irradiating the adhesive layer with ultraviolet rays before step (B).

[11] The method according to [10], wherein the first circuit member is one selected from the group consisting of a printed circuit board and a semiconductor chip, and the second circuit member is a flexible printed circuit board.

[12] A method for producing a connection body, the method including, in this order: (A) providing a laminate including a first circuit member, a second circuit member, and an adhesive layer disposed between the first circuit member and the second circuit member; (B) heating the laminate at 65 to 85° C. for 30 to 240 minutes; and (C) wire bonding the first circuit member and the second circuit member, wherein the adhesive layer is formed of the ultraviolet-irradiated product of the thermosetting adhesive composition according to [8].

[13] The method according to [12], wherein the first circuit member is one selected from the group consisting of a printed circuit board and a semiconductor chip, and the second circuit member is a flexible printed circuit board.

[14] A connection body including: a first circuit member; a second circuit member; and an adhesive layer disposed between the first circuit member and the second circuit member, wherein the adhesive layer is formed of a cured product of the thermosetting adhesive composition according to any one of [1] to [7].

[15] A connection body including: a first circuit member; a second circuit member; and an adhesive layer disposed between the first circuit member and the second circuit member, wherein the adhesive layer is formed of a cured product of the ultraviolet-irradiated product of the thermosetting adhesive composition according to [8].

### Advantageous Effects of Invention

According to the present disclosure, a thermosetting adhesive composition is provided that can suppress the occurrence of voids at the interface between a film-form adhesive and a member when a die bonding step is performed using the film-form adhesive made of the thermosetting adhesive composition. Also, according to the present disclosure, an ultraviolet-irradiated product of such a thermosetting adhesive composition is provided. Also, according to the present disclosure, an adhesive film including an adhesive layer formed of such a thermosetting adhesive composition or its ultraviolet-irradiated product is provided. Also, according to the present disclosure, a connection body using such a thermosetting adhesive composition or its ultraviolet-irradiated product and a method for producing the same are provided.

### BRIEF DESCRIPTION OF DRAWINGS

FIG. 1 is a schematic cross-sectional view showing an embodiment of a laminated film according to the present disclosure.

FIG. 2 is a schematic cross-sectional view showing a state in the manufacturing process of a semiconductor module.

FIG. 3 is a schematic cross-sectional view showing a state in the manufacturing process of a semiconductor module.

FIG. 4 is a schematic perspective view showing an example of a punched product according to the present disclosure.

FIG. 5 is a cross-sectional view taken along the line V-V shown in FIG. 4.

FIG. 6 is a schematic cross-sectional view showing a state where an adhesive piece and a cover film covering it are picked up from a base film.

FIG. 7 is a schematic cross-sectional view showing a state in the manufacturing process of a semiconductor module.

### DESCRIPTION OF EMBODIMENTS

Hereinafter, the present embodiment will be described in detail with reference to the drawings. However, the present disclosure is not limited to the following embodiments. In the following embodiments, its constituent elements (including steps, etc.) are not essential unless otherwise specified. The same or corresponding parts are denoted by the same reference signs, and redundant descriptions are omitted. Also, positional relationships such as up, down, left, and right are based on the positional relationships shown in the drawings unless otherwise specified. The size of the constituent elements in each drawing is conceptual, and the relative relationship of the size between the constituent elements is not limited to that shown in each drawing.

The same applies to the numerical values and their ranges in the present disclosure, and they do not limit the present disclosure. In this specification, a numerical range indicated using “to” indicates a range including the numerical values described before and after “to” as the minimum value and the maximum value, respectively. In the numerical ranges described stepwise in this specification, the upper limit value or the lower limit value described in one numerical range may be replaced with the upper limit value or the lower limit value of another stepwise described numerical range. Also, in the numerical ranges described in this specification, the upper limit value or the lower limit value of the numerical range may be replaced with the value shown in the examples. Also, the individually described upper limit values and lower limit values can be arbitrarily combined.

In this specification, the term “layer” includes not only a structure having a shape formed over the entire surface when observed as a plan view, but also a structure having a shape formed in a part. In this specification, the term “step” is included in this term not only as an independent step, but also if the intended action of the step is achieved even when it cannot be clearly distinguished from other steps.

In this specification, “(meth)acrylate” means at least one of acrylate and the corresponding methacrylate. The same applies to other similar expressions such as “(meth)acryloyl” and “(meth)acrylic acid”. Also, “(poly)” means both with and without the prefix “poly”.

“A or B” means that it is sufficient to include either A or B, and may include both. Also, unless otherwise specified, the materials exemplified below may be used alone or in combination of two or more. The content of each component in the composition means the total amount of the plurality of substances corresponding to each component existing in the composition, unless otherwise specified.

### [Laminated Film]

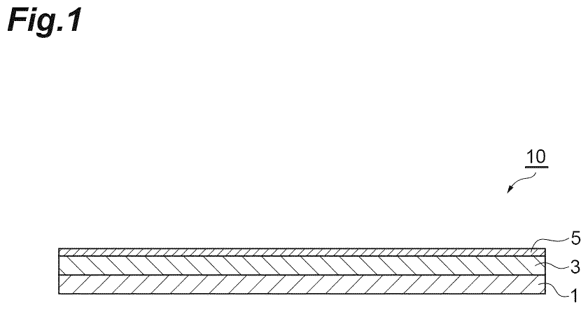

FIG. 1 is a schematic cross-sectional view showing a laminated film according to the present embodiment. The laminated film 10 shown in this figure includes a base film 1, an adhesive layer 3, and a cover film 5 in this order. The laminated film 10 has, for example, a width of 300 to 500 mm and a total length of 10 to 400 m, and is produced, for example, by being wound into a roll. Hereinafter, the configuration of the laminated film 10 will be described.

### <Base Film>

The base film 1 is not particularly limited as long as it can sufficiently withstand the tension applied in the manufacturing process of the adhesive layer 3 and the manufacturing process of the semiconductor module. The base film 1 is preferably transparent from the viewpoint of visibility of the adhesive layer 3 disposed thereon. Examples of the base film 1 include polyester-based films such as polyethylene terephthalate films; polyolefin-based films such as polytetrafluoroethylene films, polyethylene films, polypropylene films, polymethylpentene films, polyvinyl acetate films, poly-4-methylpentene-1, ethylene-vinyl acetate copolymers, ethylene-ethyl acrylate copolymers, or copolymers or mixtures thereof; and plastic films such as polyvinyl chloride films and polyimide films. The base film 1 may have a single-layer structure or a multilayer structure.

The thickness of the base film 1 may be appropriately selected within a range that does not impair workability, and is, for example, from 10 to 200 μm, and may be from 20 to 100 μm or from 25 to 80 μm. These thickness ranges are practically problem-free and economically effective ranges.

In order to increase the adhesion of the adhesive layer 3 to the base film 1, the surface of the base film 1 may be subjected to chemical or physical surface treatment such as corona treatment, chromic acid treatment, ozone exposure, flame exposure, high-pressure electric shock exposure, or ionizing radiation treatment. As the base film 1, a film with low surface energy made of a fluororesin can also be used. Examples of such a film include A-63 (release agent: modified silicone-based) manufactured by Toyobo Film Solutions Ltd., A-31 (release agent: Pt-based silicone-based) manufactured by Toyobo Film Solutions Ltd., and the like.

In order to prevent the adhesion between the base film 1 and the adhesive layer 3 from becoming excessively high, a release layer composed of a release agent such as a silicone-based release agent, a fluorine-based release agent, or a long-chain alkyl acrylate-based release agent may be formed on the surface of the base film 1.

The adhesion between the base film 1 and the adhesive layer 3 is, for example, 0.5 N/m or more. When this adhesion is 0.5 N/m or more, it is easy to prevent the adhesive layer 3 from being unintentionally peeled off from the base film 1 in the process of manufacturing the laminated film 10. Note that the adhesion of the adhesive layer 3 to the base film 1 means the 90° peel strength, and specifically, it means the peel strength measured when a sample with a width of 20 mm, in which the adhesive layer 3 is formed on the base film 1, is provided, and this adhesive layer is peeled from the base film at an angle of 90° and a peeling speed of 50 mm/min.

### <Adhesive Layer>

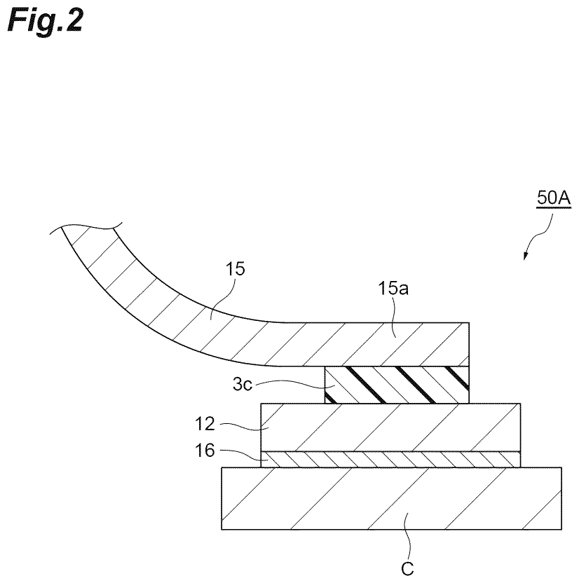

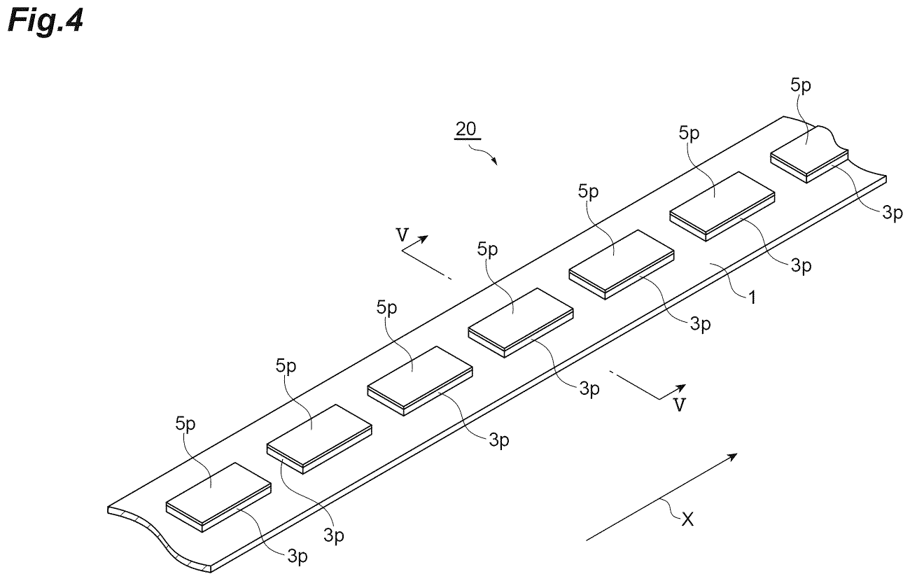

The adhesive layer 3 is used for adhesion between circuit members, and is suitably used, for example, for adhesion between a printed circuit board and a tip portion of an FPC board (flexible printed circuit board), or for adhesion between a semiconductor chip and a tip portion of an FPC board. The module 50A (connection body) shown in FIG. 2 includes a semiconductor chip C, a printed circuit board 12 (first circuit member), an adhesive piece 3c, and an FPC board 15 (second circuit member). The adhesive piece 3c adheres the printed circuit board 12 and the tip portion 15a of the FPC board 15. The adhesive piece 3c is formed of a cured product of an adhesive piece 3p (see FIG. 4). The adhesive piece 3p is obtained by processing the adhesive layer 3 shown in FIG. 1 into a predetermined shape by die-cutting. Note that the adhesive layer 16 adheres the printed circuit board 12 and the semiconductor chip C. The adhesive layer 16 may have the same composition as the adhesive piece 3c or a different composition.

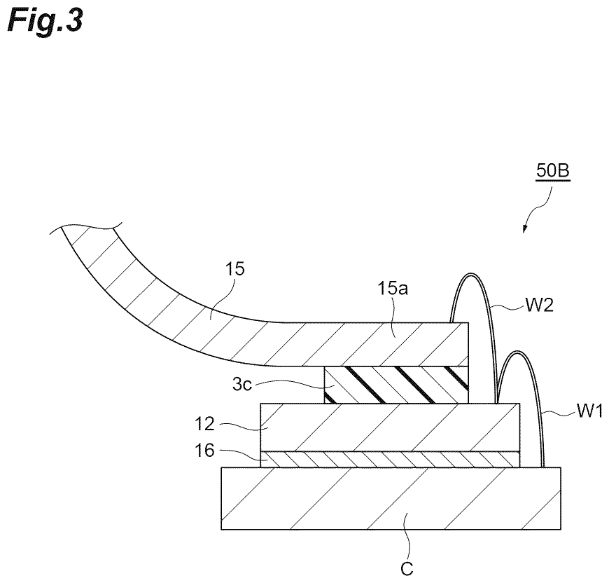

The module 50B shown in FIG. 3 is obtained by performing wire bonding on the module 50A shown in FIG. 2. A wire W1 electrically connects the semiconductor chip C and the printed circuit board 12, and a wire W2 electrically connects the printed circuit board 12 and the FPC board 15. The semiconductor chip C is, for example, a sensor chip. The printed circuit board 12 is for processing signals from the semiconductor chip C. Signals from the printed circuit board 12 are transmitted to the tip portion 15a of the FPC board 15.

The adhesive piece 3p (adhesive layer) is formed of a thermosetting adhesive composition (hereinafter, sometimes simply referred to as “adhesive composition”) or an ultraviolet-irradiated product thereof. The adhesive composition contains a thermosetting resin, a thermoplastic resin, an inorganic filler, and a photocleavable compound that cleaves upon irradiation with ultraviolet rays to generate an amine compound (hereinafter, sometimes simply referred to as “photocleavable compound”). The ultraviolet-irradiated product of the adhesive composition contains a thermosetting resin, a thermoplastic resin, an inorganic filler, and an amine compound generated from the photocleavable compound by irradiation with ultraviolet rays. The ultraviolet-irradiated product of the adhesive composition can be an adhesive composition that has been irradiated with ultraviolet rays. The thermosetting resin is a resin that cures by being heated in the presence of the amine compound. The amine compound can be, for example, a component that acts as a curing agent, a curing accelerator, or the like. The adhesive piece 3c (adhesive layer) is formed of a cured product of the adhesive composition or a cured product of the ultraviolet-irradiated product of the adhesive composition.

After being irradiated with ultraviolet rays under conditions of an illuminance of 80 mW/cm² and an integrated light quantity of 600 mJ/cm², the shear viscosity (melt viscosity) of the adhesive composition at 75° C. is from 100 to 6,000 Pa·s, and may be 500 Pa·s or more, 1,000 Pa·s or more, 2,000 Pa·s or more, or 3,000 Pa·s or more, and may be 5,500 Pa·s or less or 5,000 Pa-s or less. When the shear viscosity at 75° C. is within the above range, even if the tip portion 15a of the FPC board 15 has irregularities, the adhesive composition tends to be disposed without gaps between the tip portion 15a and the member to be adhered (printed circuit board 12). Also, when the shear viscosity at 75° C. is within the above range, after thermocompression bonding on a stage at 75° C. with a force of 30 N or more for 3 seconds or more, the occurrence of voids at the interface between the film adhesive and the member tends to be suppressed.

The shear viscosity of the above adhesive composition at 75° C. can be measured, for example, by the following procedure. First, a plurality of film-form adhesives made of the adhesive composition with a thickness of 25 μm are prepared. Subsequently, the film-form adhesive is irradiated with ultraviolet rays under conditions of an illuminance of 80 mW/cm² and an integrated light quantity of 600 mJ/cm². Next, a plurality of film-form adhesives are laminated to a thickness of about 300 μm, and this laminate is punched out with a φ9 mm punch to prepare a sample for measurement. A circular aluminum plate jig with a diameter of 8 mm is installed in a dynamic viscoelasticity analyzer, and the sample for measurement is set here. Subsequently, the shear viscosity at 75° C. can be measured by measuring while heating up to 100° C. at a heating rate of 5° C./min while applying a strain of 5% at 35° C., and obtaining the viscosity at 75° C. Note that in the measurement, the frequency is kept constant at 1 Hz, the initial load is maintained at 300 g, and the axial force is maintained at 100 g.

In order to adjust the shear viscosity at 75° C. to a predetermined range, for example, the following methods are conceivable.
Method 1: Relatively reducing the amount of the inorganic filler contained in the adhesive composition.
Method 2: Relatively reducing the amount of the thermoplastic resin (for example, acrylic rubber) contained in the adhesive composition.
Method 3: Relatively increasing the average particle size of the inorganic filler contained in the adhesive composition.
Method 4: Using a thermoplastic resin with a relatively low glass transition temperature (Tg).

After being irradiated with ultraviolet rays under conditions of an illuminance of 80 mW/cm² and an integrated light quantity of 600 mJ/cm² and further heated at 75° C. for 3 hours, the storage modulus at 35° C. is from 100 to 4,000 MPa, and may be 300 MPa or more, 500 MPa or more, 700 MPa or more, or 900 MPa or more, and may be 3,800 MPa or less, 3,500 MPa or less, 3,200 MPa or less, 3,000 MPa or less, or 2,800 MPa or less. When the storage modulus at 35° C. is within the above range, the internal stress of the adhesive piece 3c is easily relaxed, and warpage of the module 50B can be suppressed.

In order to adjust the storage modulus at 35° C. to a predetermined range, for example, the following methods are conceivable.
Method 1: Relatively increasing the amount of the thermoplastic resin (for example, acrylic rubber) contained in the adhesive composition.
Method 2: Using a thermoplastic resin with a relatively low glass transition temperature (Tg).
Method 3: Using a thermosetting resin having a flexible skeleton.

The photocleavable compound may be a compound having an α-aminoacetophenone skeleton. For example, a compound having the following α-aminoacetophenone skeleton, when irradiated with ultraviolet rays, undergoes α-cleavage and deblocking to generate, as one component, an amine compound having a radical (carboradical). The photocleavable compound may be a compound that cleaves upon irradiation with ultraviolet rays to generate an amine compound having a radical (carboradical).

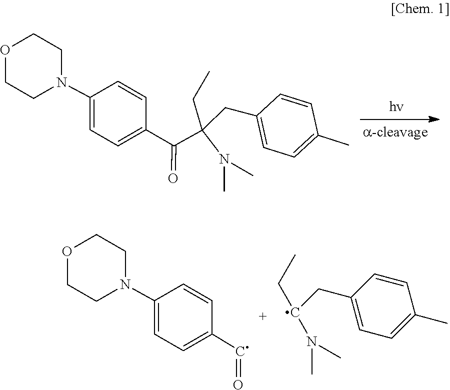

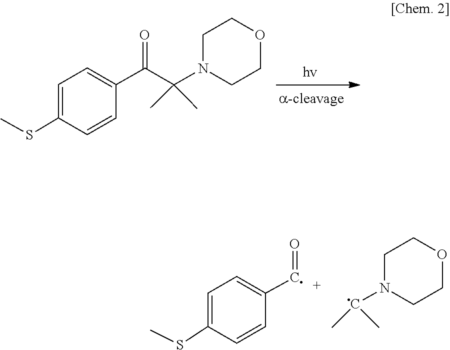

The adhesive composition may, for example, satisfy the following Condition 1.

### Condition 1

After being irradiated with ultraviolet rays under conditions of an illuminance of 80 mW/cm² and an integrated light quantity of 600 mJ/cm² and further heated at 75° C. for 3 hours, the storage modulus at 75° C. is 10 MPa or more.

It can be said that an adhesive composition satisfying Condition 1 is excellent in low-temperature curability. This provides an advantage that a member having relatively low heat resistance can be adopted as a member constituting the module 50B. To obtain an adhesive composition satisfying Condition 1, for example, it is conceivable to use a phenolic resin together with an epoxy resin as the thermosetting resin. The reason why the phenolic resin contributes to the improvement of low-temperature curability is that the reactivity between the phenolic resin and the epoxy resin is higher than the reactivity between epoxy resins, and the use of the phenolic resin facilitates the progress of the reaction.

By using the adhesive composition satisfying Condition 1, swaying of the adhesive piece 3c in the wire bonding step can be reduced, and the implementation of wire bonding becomes easy. The storage modulus according to Condition 1 may be 10 MPa or more, as described above, and may be 15 MPa or more or 20 MPa or more. The storage modulus according to Condition 1 may be, for example, 1,000 MPa or less, 900 MPa or less, or 800 MPa or less. The higher the storage modulus according to Condition 1, the easier it tends to be to implement wire bonding.

The storage modulus at 35° C. and 75° C. can be measured, for example, by the following procedure. First, a plurality of film-form adhesives made of the adhesive composition with a thickness of 25 μm are prepared. Subsequently, the film-form adhesive is irradiated with ultraviolet rays under conditions of an illuminance of 80 mW/cm² and an integrated light quantity of 600 mJ/cm². Next, a plurality of the film-form adhesives after ultraviolet irradiation are laminated to a thickness of about 300 μm, this is made into a size of 4 mm width×33 mm, and heated at 75° C. for 3 hours to prepare a sample for measurement. The prepared sample for measurement is set in a dynamic viscoelasticity analyzer with a distance between chucks of 20 mm, a tensile load is applied, and measurement is performed under conditions of a frequency of 10 Hz and a heating rate of 3° C./min to measure the storage modulus at 35° C. and 75° C.

It is preferable that the curing reaction of the adhesive composition has progressed to some extent by a heat treatment at 75° C. for 3 hours. The degree to which the reaction has progressed can be quantified by differential scanning calorimetry. That is, the reaction rate calculated by substituting the calorific value C1 and the calorific value C2, which are respectively obtained from a DSC curve obtained by differential scanning calorimetry at a heating rate of 10° C./min, into the following formula is, for example, 45% or more, and may be 50% or more, 55% or more, or 60% or more.

Reaction rate (%)=(C1−C2)/C1×100

The calorific value C1 is the calorific value (unit: J/g) for which a measurement target is a resin composition after the thermosetting adhesive composition has been irradiated with ultraviolet rays under conditions of an illuminance of 80 mW/cm² and an integrated light quantity of 600 mJ/cm². The calorific value C2 is the calorific value (unit: J/g) for which a measurement target is a resin composition after the thermosetting adhesive composition has been irradiated with ultraviolet rays under conditions of an illuminance of 80 mW/cm² and an integrated light quantity of 600 mJ/cm² and further heated at 75° C. for 3 hours. Note that the temperature range for the differential scanning calorimetry is, for example, from 30 to 300° C. The temperature range for obtaining the calorific value C1 and the calorific value C2 from the DSC curve obtained by the measurement is from 50 to 200° C. When the reaction rate is 45% or more, deterioration over time after the manufacturing process can be suppressed, and there is a tendency for excellent reliability.

The laminated film 10 can be produced, for example, as follows. First, a coating liquid is provided by dissolving the adhesive composition constituting the adhesive layer 3 in a solvent such as an organic solvent to form a varnish. After this coating liquid is coated on the base film 1, the solvent is removed to form the adhesive layer 3. Examples of the coating method include a knife coating method, a roll coating method, a spray coating method, a gravure coating method, a bar coating method, a curtain coating method, and the like. Next, the cover film 5 is attached to the surface of the adhesive layer 3 under conditions of room temperature (25° C.) to 60° C. Thereby, the laminated film 10 can be obtained. Note that it is also possible to obtain the laminated film 10 by forming the adhesive layer 3 on a wide base film, then attaching the cover film 5 to cover it to produce a laminated film, and cutting (slitting) this into a predetermined width.

### <Punched Product>

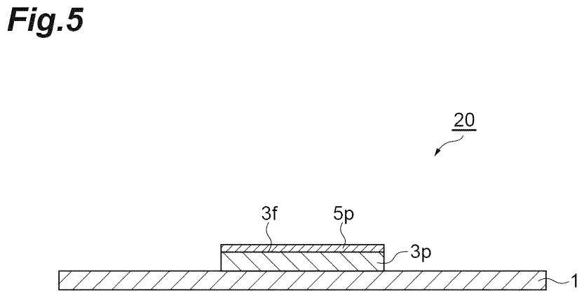

FIG. 4 is a schematic perspective view showing a punched product manufactured from the laminated film 10. FIG. 5 is a cross-sectional view taken along the line V-V shown in FIG. 4. The punched product 20 shown in FIG. 4 and FIG. 5 includes a strip-shaped base film 1 with a width of 100 mm or less, a plurality of adhesive pieces 3p arranged on the base film 1 so as to be aligned in its longitudinal direction (the direction of arrow X shown in FIG. 4), and a cover film 5p that covers the upper surface 3f of the adhesive pieces 3p and has the same shape as the adhesive pieces 3p.

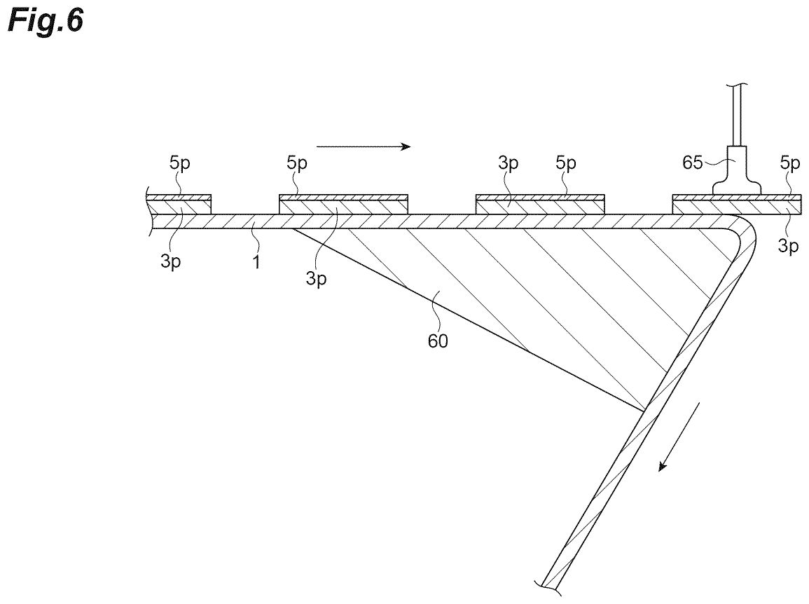

The adhesive piece 3p is suitably applied for adhesion between a circuit member (semiconductor chip or printed circuit board) and a tip portion of an FPC board. The area of the adhesive piece 3p in a plan view is, for example, from 1 to 100 mm², and may be from 3 to 50 mm² or from 5 to 40 mm². According to the punched product 20, a plurality of adhesive pieces 3p arranged so as to be aligned on the base film 1 can be sequentially picked up (see FIG. 6), and then each adhesive piece 3p can be placed in a predetermined region of a circuit member, and the adhesion between the circuit member and the FPC member can be efficiently performed.

The punched product 20 can be obtained, for example, through the following steps.
(a) Providing the laminated film 10.
(b) Obtaining a plurality of adhesive pieces 3p arranged on the base film 1 so as to be aligned in the longitudinal direction of the base film 1 by die-cutting the adhesive layer 3 and the cover film 5 in the laminated film 10.

### <Thermosetting Adhesive Composition (Adhesive Composition)>

The adhesive composition constituting the adhesive layer 3 and the adhesive piece 3p will be described. The adhesive composition, as described above, contains a thermosetting resin, a thermoplastic resin, an inorganic filler, and a photocleavable compound.

### Thermosetting Resin

The thermosetting resin is a resin that cures by being heated in the presence of an amine compound. The thermosetting resin may be, for example, an epoxy resin. Also, the thermosetting resin may be a combination of an epoxy resin and an epoxy resin curing agent.

Examples of the epoxy resin include bifunctional epoxy resins such as bisphenol A type epoxy resins, bisphenol F type epoxy resins, bisphenol S type epoxy resins, alicyclic epoxy resins, aliphatic chain epoxy resins, phenol novolac type epoxy resins, cresol novolac type epoxy resins, bisphenol A novolac type epoxy resins, diglycidyl etherified products of biphenol, diglycidyl etherified products of naphthalenediol, diglycidyl etherified products of phenols, diglycidyl ethers of alcohols, and their alkyl substituted products, halides, and hydrogenated products; novolac type epoxy resins, and the like. Also, other generally known epoxy resins such as polyfunctional epoxy resins and heterocyclic-containing epoxy resins may be applied. Note that components other than the epoxy resin may be included as impurities within a range that does not impair the properties.

The epoxy resin may, for example, include an epoxy resin that is solid at 25° C. (hereinafter, sometimes referred to as “solid epoxy resin”). That is, the epoxy resin may be composed of a solid epoxy resin and an epoxy resin that is liquid at 25° C. (hereinafter, sometimes referred to as “liquid epoxy resin”). When the epoxy resin includes a solid epoxy resin, it is not sticky during film formation, and sticking to machines such as rolls can be suppressed, and there is a tendency that a decrease in workability when producing a laminated film can be suppressed.

Specific examples of the solid epoxy resin include YDCN-700-10 (manufactured by NIPPON STEEL CHEMICAL & MATERIAL CO., LTD., cresol novolac type epoxy resin), N-500P-10 (manufactured by DIC Corporation, cresol novolac type epoxy resin), HP-4710 (manufactured by DIC Corporation, naphthalene type epoxy resin), NC-7000L (manufactured by Nippon Kayaku Co., Ltd., naphthalene type epoxy resin), and the like.

Specific examples of the liquid epoxy resin include YDF-8170C (manufactured by NIPPON STEEL CHEMICAL & MATERIAL CO., LTD., bisphenol F type epoxy resin), EPICLON (registered trademark) series (EXA-830CRP, 830, 830-S, 835, etc.) (manufactured by DIC Corporation, bisphenol F type epoxy resin), and the like.

As the epoxy resin curing agent, a commonly used known curing agent can be used. Examples of the epoxy resin curing agent include amines, polyamides, acid anhydrides, polysulfides, boron trifluoride, phenolic resins, and the like. The epoxy resin curing agent may be, for example, a phenolic resin.

The phenolic resin is not particularly limited as long as it has a phenolic hydroxyl group in the molecule. Examples of the phenolic resin include novolac type phenolic resins obtained by condensing or co-condensing phenols such as phenol, cresol, resorcinol, catechol, bisphenol A, bisphenol F, phenylphenol, and aminophenol and/or naphthols such as α-naphthol, β-naphthol, and dihydroxynaphthalene with a compound having an aldehyde group such as formaldehyde under an acidic catalyst; phenol aralkyl resins, naphthol aralkyl resins, biphenyl aralkyl type phenolic resins, and phenyl aralkyl type phenolic resins synthesized from phenols and/or naphthols such as allylated bisphenol A, allylated bisphenol F, allylated naphthalenediol, phenol novolac, and phenol, and dimethoxyparaxylene or bis(methoxymethyl)biphenyl, and the like.

The content of the thermosetting resin (for example, the total of the epoxy resin and the phenolic resin) is, for example, from 35 to 75% by mass, and may be from 40 to 70% by mass or from 45 to 65% by mass, based on the total amount of the adhesive composition. When the content of the thermosetting resin is within the above range, shrinkage accompanying the thermosetting of the adhesive layer 3 can be suppressed, and excellent adhesion after thermosetting tends to be easily achieved.

The content of the epoxy resin is, for example, from 15 to 45% by mass, and may be from 20 to 40% by mass or from 25 to 35% by mass, based on the total amount of the adhesive composition. When the content of the epoxy resin is within the above range, sufficient thermosetting properties are obtained, and curing tends to proceed even at low temperatures.

The content of the solid epoxy resin with respect to the total amount of the epoxy resin may be, for example, 10% by mass or more, 12% by mass or more, or 15% by mass or more, and may be 60% by mass or less, 55% by mass or less, 50% by mass or less, 45% by mass or less, 40% by mass or less, 35% by mass or less, or 30% by mass or less. When the content of the solid epoxy resin is within the above range, it is not sticky during film formation, and sticking to machines such as rolls can be suppressed, and a decrease in workability when producing a laminated film can be suppressed.

The content of the solid epoxy resin is, for example, 4% by mass or more, 4.5% by mass or more, or 5% by mass or more, and may be 25% by mass or less, 20% by mass or less, 18% by mass or less, 15% by mass or less, 12% by mass or less, 10% by mass or less, or 8% by mass or less, based on the total amount of the adhesive composition. When the content of the solid epoxy resin is within the above range, it is not sticky during film formation, and sticking to machines such as rolls can be suppressed, and a decrease in workability when producing a laminated film can be suppressed.

The content of the phenolic resin is, for example, from 5 to 45% by mass, and may be from 10 to 40% by mass or from 15 to 35% by mass, based on the total amount of the adhesive composition.

### Thermoplastic Resin

As the thermoplastic resin, a resin having thermoplasticity, or a resin that has thermoplasticity at least in an uncured state and forms a crosslinked structure after heating can be used. From the viewpoint of excellent shrinkability, heat resistance, and peelability, the thermoplastic resin may be a (meth)acrylic copolymer having a reactive group (hereinafter, also referred to as “reactive group-containing (meth)acrylic copolymer”).

When the thermoplastic resin includes a reactive group-containing (meth)acrylic copolymer, the adhesive composition may be an embodiment that does not contain a thermosetting resin. That is, the adhesive composition may be an embodiment that contains a reactive group-containing (meth)acrylic copolymer, an inorganic filler, and a photocleavable compound.

Examples of the (meth)acrylic copolymer include (meth)acrylic acid ester copolymers such as acrylic glass and acrylic rubber. The (meth)acrylic copolymer may be an acrylic rubber. The acrylic rubber may be formed by copolymerization of a monomer selected from (meth)acrylic acid esters and acrylonitrile, with an acrylic acid ester as a main component.

Examples of the (meth)acrylic acid ester include methyl (meth)acrylate, ethyl (meth)acrylate, propyl (meth)acrylate, isopropyl (meth)acrylate, butyl (meth)acrylate, isobutyl (meth)acrylate, hexyl (meth)acrylate, cyclohexyl (meth)acrylate, 2-ethylhexyl (meth)acrylate, lauryl (meth)acrylate, and the like. Examples of the (meth)acrylic acid ester copolymer include a copolymer containing butyl acrylate and acrylonitrile as copolymer components, and a copolymer containing ethyl acrylate and acrylonitrile as copolymer components.

The reactive group-containing (meth)acrylic copolymer may be a reactive group-containing (meth)acrylic copolymer that includes a (meth)acrylic monomer having a reactive group as a copolymer component. Such a reactive group-containing (meth)acrylic copolymer can be obtained by copolymerizing a monomer mixture containing a (meth)acrylic monomer having a reactive group and the above-mentioned monomers.

Examples of the reactive group include an epoxy group, a carboxyl group, a (meth)acryloyl group, a hydroxyl group, an episulfide group, and the like, from the viewpoint of improving heat resistance. The reactive group may be an epoxy group or a carboxyl group from the viewpoint of crosslinkability.

In the present embodiment, the reactive group-containing (meth)acrylic copolymer may be an epoxy group-containing (meth)acrylic copolymer that includes a (meth)acrylic monomer having an epoxy group as a copolymer component. In this case, examples of the (meth)acrylic monomer having an epoxy group include glycidyl (meth)acrylate, 4-hydroxybutyl (meth)acrylate glycidyl ether, 3,4-epoxycyclohexylmethyl (meth)acrylate, and the like. The (meth)acrylic monomer having a reactive group may be glycidyl (meth)acrylate from the viewpoint of heat resistance.

The glass transition temperature (Tg) of the thermoplastic resin is, for example, from −50 to 20° C., and may be from −30 to 15° C. When the Tg of the thermoplastic resin is −50° C. or higher, it is easy to suppress the adhesive layer 3 from becoming excessively soft, and excellent handleability and adhesiveness can be achieved. On the other hand, when the Tg of the thermoplastic resin is 0° C. or lower, it is easy to ensure the flexibility of the adhesive layer 3, and excellent adhesive strength can be achieved. In addition to this, even if irregularities exist on the surface of the adherend, the adhesive layer 3 easily follows the irregularities, and excellent adhesiveness can be exhibited.

The Tg of the thermoplastic resin is a midpoint glass transition temperature value obtained by differential scanning calorimetry (DSC). Specifically, the Tg of the thermoplastic resin is a midpoint glass transition temperature calculated by a method compliant with JIS K7121:1987, by measuring the change in calorific value under conditions of a heating rate of 10° C./min and a measurement temperature of −80 to 80° C. Note that when the thermoplastic resin is a commercially available product, a value described in a catalog or the like may be adopted.

The weight-average molecular weight of the thermoplastic resin may be from 100,000 to 2,000,000. When the weight-average molecular weight is 100,000 or more, it becomes easy to ensure heat resistance. On the other hand, when the weight-average molecular weight is 2,000,000 or less, it is easy to suppress a decrease in flow and a decrease in applicability. The weight-average molecular weight of the thermoplastic resin may be from 400,000 to 1,500,000 or from 500,000 to 1,200,000. Note that the weight-average molecular weight is a polystyrene-equivalent value using a calibration curve by standard polystyrene in gel permeation chromatography (GPC).

The content of the thermoplastic resin is, for example, from 5 to 35% by mass, and may be from 8 to 33% by mass, from 12 to 30% by mass, or from 15 to 27% by mass, based on the total amount of the adhesive composition. When the content of the thermosetting resin is within the above range, shrinkage accompanying the thermosetting of the adhesive layer 3 can be suppressed, and excellent adhesion after thermosetting tends to be easily achieved.

### Inorganic Filler

The inorganic filler can be selected according to the desired function. Examples of the inorganic filler include metal (conductive) fillers such as silver powder, gold powder, and copper powder; and non-metal (insulating) fillers such as silica, alumina, boron nitride, titania, glass, iron oxide, and ceramics. The inorganic filler may be, for example, a silica filler.

The surface of the inorganic filler may have an organic group. By modifying the surface of the inorganic filler with an organic group, the dispersibility in an organic solvent when preparing a varnish for forming the adhesive layer 3 can be improved. In addition to this, shrinkage accompanying the thermosetting of the adhesive layer 3 can be suppressed, and a high elastic modulus and excellent peelability of the adhesive layer 3 tend to be easily compatible. The inorganic filler having an organic group on its surface can be obtained, for example, by mixing a silane coupling agent represented by the following formula (B-1) and an inorganic filler, and stirring at a temperature of 30° C. or higher. The fact that the surface of the inorganic filler is modified with an organic group can be confirmed by ultraviolet-visible spectroscopy, infrared absorption spectroscopy, X-ray photoelectron spectroscopy, or the like.

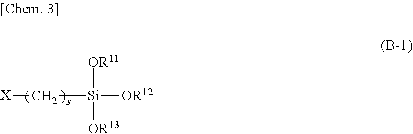

In formula (B-1), X represents an organic group selected from the group consisting of a phenyl group, a glycidoxy group, a (meth)acryloyloxy group, a mercapto group, an amino group, a vinyl group, an isocyanate group, and a methacryloxy group, s represents 0 or an integer of 1 to 10, and R¹¹, R¹², and R¹³ each independently represent an alkyl group having 1 to 10 carbon atoms.

Examples of the alkyl group having 1 to 10 carbon atoms include a methyl group, an ethyl group, a propyl group, a butyl group, a pentyl group, a hexyl group, a heptyl group, an octyl group, a nonyl group, a decyl group, an isopropyl group, an isobutyl group, and the like.

The alkyl group having 1 to 10 carbon atoms may be a group selected from the group consisting of a methyl group, an ethyl group, and a pentyl group from the viewpoint of availability. X may be a group selected from the group consisting of an amino group, a glycidoxy group, a mercapto group, and an isocyanate group from the viewpoint of heat resistance, and may be a glycidoxy group or a mercapto group.

s may be an integer of 0 to 5, and may be an integer of 0 to 4, from the viewpoint of suppressing film fluidity at high temperatures and improving heat resistance.

The content of the inorganic filler may be 45% by mass or less, based on the total amount of the adhesive composition. When the content of the inorganic filler is 45% by mass or less, based on the total amount of the adhesive composition, the occurrence of voids tends to be suppressed at the interface between the film-form adhesive and the member in the die bonding step. The content of the inorganic filler may be 40% by mass or less, 30% by mass or less, 20% by mass or less, or 10% by mass or less, and may be 0.1% by mass or more, 0.5% by mass or more, 1% by mass or more, 3% by mass or more, 5% by mass or more, 10% by mass or more, 15% by mass or more, 20% by mass or more, 25% by mass or more, or 30% by mass or more, based on the total amount of the adhesive composition.

### Photocleavable Compound

The photocleavable compound is one that cleaves upon irradiation with ultraviolet rays to generate an amine compound. As described above, the photocleavable compound may be, for example, a compound having an α-aminoacetophenone skeleton. Examples of such a compound include Omnirad 907 (2-methyl-1-[4-(methylthio)phenyl]-2-morpholinopropan-1-one, manufactured by IGM Resins B.V.), Omnirad 379EG (2-dimethylamino-2-(4-methyl-benzyl)-1-(4-morpholin-4-yl-phenyl)-butan-1-one, manufactured by IGM Resins B.V.), and the like. The photocleavable compound may be Omnirad 379EG. Omnirad 379EG has a highly basic aliphatic amine, and it is considered that, for example, proton abstraction from a phenolic resin easily occurs, and the curing reaction easily proceeds. Note that Omnirad is a registered trademark. As the photocleavable compound, a photoradical generator that generates radicals upon irradiation with ultraviolet rays, or a photobase generator that generates a base may be used. Examples of the photobase generator include the WPBG series manufactured by FUJIFILM Corporation. Specific examples of the photobase generator include WPBG-027, WPBG-140, WPBG-165, and the like.

The content of the photocleavable compound is, for example, from 0.1 to 5% by mass, and may be from 0.5 to 4.5% by mass, from 1 to 4% by mass, or from 2 to 3.5% by mass, based on the total amount of the adhesive composition. When the content of the photocleavable compound is within the above range, thermosetting can be promoted, and work life tends to be secured.

The adhesive composition may further contain other components. Examples of other components include coupling agents such as silane coupling agents; and organic fillers such as carbon, rubber-based fillers, silicone fine particles, polyamide fine particles, and polyimide fine particles. The content of other components may be from 0 to 30% by mass, based on the total amount of the adhesive composition.

### Organic Solvent

The adhesive composition may be diluted with an organic solvent as needed, and may be used as an adhesive varnish. The organic solvent is not particularly limited, but can be determined by considering volatility during film formation from the boiling point. Examples of the organic solvent include relatively low-boiling point solvents such as methanol, ethanol, 2-methoxyethanol, 2-ethoxyethanol, 2-butoxyethanol, methyl ethyl ketone, acetone, methyl isobutyl ketone, toluene, and xylene; and relatively high-boiling point solvents such as dimethylacetamide, dimethylformamide, N-methyl-2-pyrrolidone, and cyclohexanone. Relatively low-boiling point solvents have the advantage that curing of the film is less likely to proceed during film formation. Relatively high-boiling point solvents have the advantage of improving film formability.

The thickness of the adhesive layer 3 may be appropriately selected within a range that does not impair workability, and is, for example, from 1 to 200 μm, and may be from 5 to 150 μm or from 10 to 150 μm. When the thickness of the adhesive layer 3 is 1 μm or more, it is easy to ensure sufficient adhesiveness, while when it is 200 μm or less, the adhesive composition constituting the adhesive layer 3 tends to be easily suppressed from protruding from the base film 1 or the cover film 5.

### <Cover Film>

The cover film 5 is not particularly limited as long as it can be easily peeled from the adhesive layer 3. Examples of the cover film 5 include polyester-based films such as polyethylene terephthalate films; polyolefin-based films such as polytetrafluoroethylene films, polyethylene films, polypropylene films, polymethylpentene films, polyvinyl acetate films, poly-4-methylpentene-1, ethylene-vinyl acetate copolymers, ethylene-ethyl acrylate copolymers, or copolymers or mixtures thereof; and plastic films such as polyvinyl chloride films and polyimide films. The cover film 5 may have a single-layer structure or a multilayer structure.

When the cover film 5 has a multilayer structure, it may be a pressure-sensitive adhesive film, and specifically, it may be a dicing pressure-sensitive adhesive film (manufactured by Maxell, Ltd.). The pressure-sensitive adhesive film may have a pressure-sensitive adhesive layer and a base material layer. In this case, the pressure-sensitive adhesive layer may be configured to be in contact with the adhesive layer 3. As the pressure-sensitive adhesive layer, a photocurable pressure-sensitive adhesive layer or a non-photocurable pressure-sensitive adhesive layer can be used, and as the base material layer, the above-mentioned plastic films or the like can be used.

The adhesion between the adhesive layer 3 and the cover film 5 is, for example, 70 N/m or less, and may be 50 N/m or less or 20 N/m or less. In particular, when the adhesive layer 3 is made of the adhesive composition, it is preferable that the adhesion of the cover film 5 to the adhesive layer 3 is within the above range after a heat treatment at 75° C. for 1 second. When this adhesion is 70 N/m or less, after the adhesive layer 3 in a state covered with the cover film 5 is temporarily pressure-bonded to an adherend (for example, a substrate) under conditions of 75° C. for 0.5 seconds, the cover film 5 can be easily peeled from the semi-cured adhesive layer 3 with a pressure-sensitive adhesive tape or the like. Note that the adhesion of the cover film 5 to the adhesive layer 3 means the 90° peel strength, and specifically, it means the peel strength measured when a sample in which a cover film of the same width is disposed on an adhesive layer of 20 mm width made of the same composition as the adhesive layer 3 is provided, and this cover film is peeled from the adhesive layer at an angle of 90° and a peeling speed of 50 mm/min. When the cover film 5 is a pressure-sensitive adhesive film having a photocurable pressure-sensitive adhesive layer, the adhesion may be a value after light irradiation.

The thickness of the cover film 5 may be appropriately selected within a range that does not impair workability, and is, for example, from 10 to 200 μm, and may be from 10 to 180 μm or from 15 to 140 μm. These thickness ranges are practically problem-free and economically effective ranges.

### [Method for Producing a Connection Body (Semiconductor Module)]

A method for producing the module 50B (connection body) shown in FIG. 3 using the punched product 20 will be described. FIG. 6 is a schematic cross-sectional view showing a state where the adhesive piece 3p and the cover film 5p covering it are picked up from the base film 1. While applying a certain tension to the punched product 20, the punched product 20 is moved in the direction of the arrow shown in FIG. 6 while bringing the surface on the base film 1 side of the punched product 20 into contact with the wedge-shaped member 60. As a result, as shown in FIG. 6, the front of the adhesive piece 3p and the cover film 5p is in a state of being lifted from the base film 1. In this state, for example, the adhesive piece 3p and the cover film 5p are picked up by a pickup device 65 having a suction force.

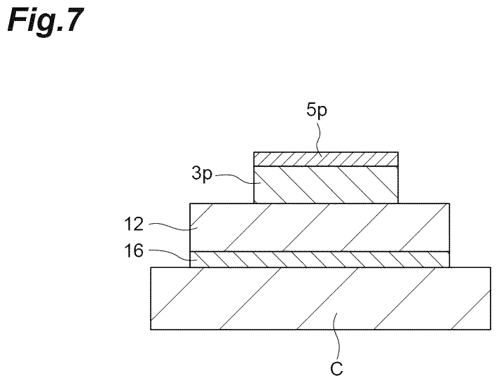

Next, the adhesive piece 3p in a state covered with the cover film 5p is placed on the surface 12a of the printed circuit board 12 (see FIG. 7). When the adhesive piece 3p is formed of the adhesive composition, for example, in this state, the adhesive piece 3p is irradiated with ultraviolet rays. The illuminance of the ultraviolet rays can be, for example, from 10 to 200 mW/cm². The integrated light quantity of the ultraviolet rays can be, for example, from 300 to 900 mJ/cm². By irradiating the adhesive piece 3p with ultraviolet rays, the adhesive piece 3p can be formed of the ultraviolet-irradiated product of the adhesive composition. Thereafter, temporary pressure bonding of the adhesive piece 3p to the printed circuit board 12 is performed. The temporary pressure bonding can be performed, for example, under conditions of a temperature of 60 to 85° C. and a pressing force of 0.1 to 2 MPa for 0.1 to 10 seconds. By the temporary pressure bonding, the adhesive piece 3p is semi-cured, thereby improving the adhesive strength to the surface 12a. Thereafter, the cover film 5p is peeled from the adhesive piece 3p using a pressure-sensitive adhesive tape or the like. As a result, the surface F1 of the adhesive piece 3p is exposed.

The adhesion of the tip portion 15a of the FPC board 15 to the printed circuit board 12 includes pressure-bonding the tip portion 15a to the adhesive piece 3p, and thereafter, curing the adhesive piece 3p by heating. That is, first, after placing the tip portion 15a of the FPC board 15 on the upper surface 3f of the adhesive piece 3p, the tip portion 15a is pressure-bonded to the adhesive piece 3p. As a result, a laminate including the printed circuit board 12, the FPC board 15, and the adhesive piece 3p is obtained (step (A)). The pressure bonding can be performed, for example, under conditions of a temperature of 60 to 85° C. and a pressing force of 0.1 to 3 MPa for 0.1 to 10 seconds.

Next, a curing process of the adhesive piece 3p is performed. The curing process can be performed, for example, at a temperature of 65 to 85° C. for 30 to 240 minutes. As a result, the adhesive piece 3p becomes the adhesive piece 3c formed of a cured product of the adhesive composition or a cured product of the ultraviolet-irradiated product of the adhesive composition, and the module 50A shown in FIG. 2 is obtained (step (B)). Note that from the viewpoint of the heat resistance of the members constituting the module 50A, the heating conditions in the above conditions 1 and 2 are set to 75° C. for 3 hours. By making the temperature at which the module 50A is heated relatively low, there is an advantage that the choice of materials is expanded.

Wire bonding is performed on the module 50A (step (C)). As a result, the module 50B shown in FIG. 3 is obtained. Thereafter, the semiconductor module is completed through processes such as protecting the wires W1 and W2 of the module 50B with a resin material, and a heat treatment in which the curing reaction of the adhesive piece 3c proceeds. Note that an adhesive piece that has already been irradiated with ultraviolet rays may be used for the production of the connection body. When producing a connection body using this adhesive piece, step (A), step (B), and step (C) can be performed sequentially.

Although the embodiments of the present disclosure have been described in detail above, the present disclosure is not limited to the above embodiments. For example, in the above embodiments, the case where the adhesive piece 3p made of the adhesive composition is provided in advance by die-cutting has been exemplified, but an adhesive layer may be formed by providing a coating liquid containing the adhesive composition and coating it on the surface of the printed circuit board 12.

### EXAMPLES

Hereinafter, the present disclosure will be specifically described with reference to examples, but the present disclosure is not limited to these examples.

### Examples 1 to 9 and Comparative Examples 1 to 4

### [Fabrication of Laminated Film]

### <Preparation of Materials>

To prepare the adhesive varnishes of the Examples and Comparative Examples, the following materials were provided.

### (1) Thermosetting Resin

### (1-1) Epoxy Resin

EXA-830CRP (trade name, manufactured by DIC Corporation, bisphenol F type epoxy resin, epoxy equivalent: 160 g/eq, liquid at 25° C.)
N-500P-10 (trade name, manufactured by DIC Corporation, cresol novolac type epoxy resin, epoxy equivalent: 204 g/eq, solid at 25° C.)

### (1-2) Phenolic Resin

MEH-7800M (trade name, manufactured by Meiwa Plastic Industries, Ltd. (now UBE Corporation), phenyl aralkyl type phenolic resin, hydroxyl equivalent: 174 g/eq)
H-4 (trade name, manufactured by Meiwa Plastic Industries, Ltd. (now UBE Corporation), phenyl aralkyl type phenolic resin, hydroxyl equivalent: 105 g/eq)

### (2) Thermoplastic Resin

SG-P3 solvent-modified product (trade name, manufactured by Nagase ChemteX Corporation, acrylic resin, weight-average molecular weight: 800,000, Tg: 12° C.)

### (3) Inorganic Filler

SC-2050-HLG (trade name, manufactured by Admatechs Co., Ltd., surface-treated silica filler)

### (4) Photocleavable Compound

Omnirad 379EG (trade name, manufactured by IGM Resins B.V.)

### (5) Coupling Agent

A-189 (trade name, manufactured by Momentive Performance Materials Japan LLC, γ-mercaptopropyltrimethoxysilane, silane coupling agent)
Z-6119 (trade name, manufactured by Dow Toray Co., Ltd., 3-ureidopropyltriethoxysilane, silane coupling agent)

### (6) Organic Solvent

Cyclohexanone

An adhesive varnish was obtained by mixing the materials and solvent shown in Table 1 and Table 2 and performing vacuum deaeration. This adhesive varnish was coated on a 38 μm thick surface-release-treated PET film as a base film. After a drying step, a 25 μm thick film-form adhesive (adhesive layer) was formed on one surface of the PET film to obtain first laminated films of Examples 1 to 9 and Comparative Examples 1 to 4, including a base film, an adhesive layer, and a cover film. Subsequently, by attaching a dicing pressure-sensitive adhesive film as a cover film to the surface of the film-form adhesive of the first laminated film, second laminated films of Examples 1 to 9 and Comparative Examples 1 to 4, including a base film, an adhesive layer, and a cover film, were obtained. A plurality of first laminated films and second laminated films were provided.

### [Evaluation of Laminated Film (Film-Form Adhesive)]

### <Measurement of Shear Viscosity>

The film-form adhesive of each first laminated film was irradiated with ultraviolet rays under conditions of an illuminance of 80 mW/cm² and an integrated light quantity of 600 mJ/cm². The shear viscosity at 75° C. of the film-form adhesive after ultraviolet irradiation (B-stage state after ultraviolet irradiation, before heating at 75° C. for 3 hours) was measured by the following method. That is, a plurality of 25 μm thick film-form adhesives were laminated to a thickness of about 300 μm, and this laminate was punched out with a φ9 mm punch to prepare a sample for measurement. A circular aluminum plate jig with a diameter of 8 mm was installed in a dynamic viscoelasticity analyzer ARES (manufactured by TA Instruments), and the sample for measurement was further set here. Thereafter, measurement was performed while heating up to 100° C. at a heating rate of 5° C./min while applying a strain of 5% at 35° C. The frequency was kept constant at 1 Hz, the initial load was maintained at 300 g, and the axial force was maintained at 100 g. The results are shown in Table 1 and Table 2.

### <Measurement of Storage Modulus>

The film-form adhesive of each first laminated film was irradiated with ultraviolet rays under conditions of an illuminance of 80 mW/cm² and an integrated light quantity of 600 mJ/cm². A plurality of 25 μm thick film-form adhesives were laminated to a thickness of about 300 μm, this was made into a size of 4 mm width×33 mm, and heated at 75° C. for 3 hours to obtain a sample for measurement. The sample for measurement was set in a dynamic viscoelasticity analyzer (Rheogel E-4000 (trade name), manufactured by UBM Co., Ltd.) with a distance between chucks of 20 mm, a tensile load was applied, and measurement was performed under conditions of a frequency of 10 Hz and a heating rate of 3° C./min to measure the storage modulus at 35° C. and 75° C. The results are shown in Table 1 and Table 2.

### <Measurement of Calorific Value and Calculation of Reaction Rate>

The reaction rate of the film-form adhesive was measured by the following method. That is, the film-form adhesive was irradiated with ultraviolet rays under conditions of an illuminance of 80 mW/cm² and an integrated light quantity of 600 mJ/cm². 10 mg of the film-form adhesive after ultraviolet irradiation was weighed in an aluminum pan (manufactured by Epolead Service Co., Ltd.), an aluminum lid was placed on it, and the evaluation sample was sealed in the sample pan using a crimper. Using a differential scanning calorimeter (Thermo plus DSC8235E, manufactured by Rigaku Corporation), DSC was measured under a nitrogen atmosphere at a heating rate of 10° C./min and a measurement temperature range of 30 to 300° C. As a means of analyzing the calorific value, a partial area analysis method was used. By giving an analysis instruction in the temperature range of 50 to 200° C. of the DSC curve, the total calorific value (unit: J/g) was calculated by specifying the baseline of the analysis temperature range and integrating the peak area. This was taken as the calorific value C1.

The film-form adhesive after ultraviolet irradiation was placed in an oven set at 75° C. and heat-treated for 3 hours. Using the sample after the heat treatment, the calorific value (unit: J/g) in the temperature range of 50 to 200° C. was calculated in the same procedure as before the heat treatment as described above, and this was taken as the calorific value C2 after the heat treatment. The reaction rate was calculated by substituting the obtained values of the two calorific values C1 and C2 into the following formula. The results are shown in Table 1 and Table 2.

Reaction rate (%)=(C1−C2)/C1×100

### <Measurement of Peel Strength Against Polyimide Film (PI Peel Strength)>

The peel strength of the film-form adhesive of each second laminated film against a polyimide film was measured by the following method. First, the film-form adhesive of each second laminated film was irradiated with ultraviolet rays under conditions of an illuminance of 80 mW/cm² and an integrated light quantity of 600 mJ/cm². Thereafter, the second laminated film was punched out to a size of 3.2 mm×3.2 mm. After peeling the base film from the second laminated film, the film-form adhesive was attached to an organic substrate and temporarily pressure-bonded on a stage at 75° C. with a pressure of 1.0 N for 0.5 seconds. Next, the cover film was peeled from the film-form adhesive, a polyimide film (Upilex 50S (trade name), manufactured by Ube Industries, Ltd.) of size 5 mm×100 mm was attached to the film-form adhesive, and final pressure bonding was performed on a stage at 75° C. with a force of 30 N for 3 seconds. Thereafter, the film-form adhesive was cured by heating at 75° C. for 3 hours to obtain a measurement sample. The PI peel strength was measured with a 90-degree peel tester (manufactured by Tester Sangyo Co., Ltd.) at a test speed of 50 mm/min. The results are shown in Table 1 and Table 2.

<Confirmation of Voids after Thermocompression Bonding>

The film-form adhesive of each second laminated film was irradiated with ultraviolet rays under conditions of an illuminance of 80 mW/cm² and an integrated light quantity of 600 mJ/cm². Thereafter, the second laminated film was punched out to a size of 3.2 mm×3.2 mm. After peeling the base film from the second laminated film, the film-form adhesive was attached to an organic substrate and temporarily pressure-bonded on a stage at 75° C. with a pressure of 1.0 N for 0.5 seconds. Next, the cover film was peeled from the film-form adhesive, a polyimide film (Upilex 50S (trade name), manufactured by Ube Industries, Ltd.) of size 5 mm×100 mm was attached to the film-form adhesive, and final pressure bonding was performed on a stage at 75° C. with a force of 30 N for 3 seconds to prepare a test piece. Thereafter, the test piece was visually observed for the presence of voids from the polyimide film side, and the case where no voids were observed and it was predicted that no voids would be observed even if a plurality of test pieces were prepared was evaluated as “A”, the case where no voids were observed but there was a possibility that voids would be observed in some parts when a plurality of test pieces were prepared was evaluated as “B”, and the case where voids were observed was evaluated as “C”. The results are shown in Table 1 and Table 2.

TABLE 1

| | | Exam. | Exam. | Exam. | Exam. | Exam. | Exam. | Exam. | Exam. | Exam. |
|---|---|---|---|---|---|---|---|---|---|---|
| | | 1 | 2 | 3 | 4 | 5 | 6 | 7 | 8 | 9 |
| Thermosetting | EXA-830CRP | 13.8 | 13.8 | 15.3 | 18.8 | 24.2 | 26.4 | 26.4 | 26.4 | 26.4 |
| resin | (Liquid epoxy resin) | | | | | | | | | |
| | N-500P-10 | 14.9 | 14.9 | 16.5 | 4.7 | 6.1 | 6.6 | 6.6 | 6.6 | 6.6 |
| | (Solid epoxy resin) | | | | | | | | | |
| | MEH-7800M | 23.2 | 23.2 | — | 21.5 | 27.7 | 30.3 | 30.3 | 30.3 | 30.3 |
| | (Phenolic resin) | | | | | | | | | |
| | H-4 | — | — | 15.5 | — | — | — | — | — | — |
| | (Phenolic resin) | | | | | | | | | |
| Thermoplastic | SG-P3 solvent- | 16.3 | 16.3 | 18.0 | 12.0 | 9.0 | 30.7 | 28.7 | 23.7 | 32.2 |
| resin | modified product | | | | | | | | | |
| Inorganic filler | SC-2050-HLG | 28.5 | 28.5 | 31.5 | 40.0 | 30.0 | 3.0 | 5.0 | 10.0 | 1.5 |
| Photocleavable | Omnirad379EG | 2.0 | 3.0 | 3.3 | 3.0 | 3.0 | 3.0 | 3.0 | 3.0 | 3.0 |
| compound | | | | | | | | | | |
| Coupling agent | A-189 | 0.09 | 0.09 | — | — | — | — | — | — | — |
| | Z-6119 | 0.18 | 0.18 | — | — | — | — | — | — | — |

| | | | | | | | | | |
|---|---|---|---|---|---|---|---|---|---|
| 75 °C shear viscosity (Pa · s) | 2648 | 2471 | 3267 | 1799 | 166 | 4838 | 4551 | 2769 | 5739 |
| 35 °C storage modulus (MPa) | 1378 | 1480 | 1000 | 3315 | 3840 | 449 | 572 | 964 | 320 |
| 75 °C storage modulus (MPa) | 54 | 248 | 71 | 841 | 341 | 51 | 68 | 117 | 17 |
| Reaction rate (%) | 46 | 58 | 48 | 68 | 68 | 59 | 58 | 62 | 49 |
| PI peel strength (N/m) | 83 | 83 | 34 | 142 | 72 | 220 | 160 | 121 | 188 |
| Voids after thermocompression bonding | B | B | B | A | A | B | B | B | B |

TABLE 2

| | | Comp. | Comp. | Comp. | Comp. |
|---|---|---|---|---|---|
| | | Exam. 1 | Exam. 2 | Exam. 3 | Exam. 4 |
| Thermosetting resin | EXA-830CRP | 19.1 | — | 13.4 | 26 |
| | (Liquid epoxy resin) | | | | |
| | N-500P-10 | 4.8 | — | 3.3 | 2.9 |
| | (Solid epoxy resin) | | | | |
| | MEH-7800M | 21.9 | — | 15.3 | 13.1 |
| | (Phenolic resin) | | | | |
| | H-4 | — | — | — | — |
| | (Phenolic resin) | | | | |
| Thermoplastic resin | SG-P3 solvent- | 24.3 | 100 | 15.0 | 26.0 |
| | modified product | | | | |
| Inorganic filler | SC-2050-HLG | 26.8 | — | 50.0 | 29.0 |
| Photocleavable compound | Omnirad379EG | 3.0 | — | 3.0 | 3.0 |
| Coupling agent | A-189 | — | — | — | — |
| | Z-6119 | — | — | — | — |

| 75 °C shear viscosity (Pa · s) | 7170 | 25156 | 11849 | 7397 |
|---|---|---|---|---|
| 35 °C storage modulus (MPa) | 586 | 12 | 2461 | 204 |
| 75 °C storage modulus (MPa) | 83 | 1.1 | 1257 | 46 |
| Reaction rate (%) | 58 | Not | 66 | 83 |
| | | measurable | | |
| PI peel strength (N/m) | 205 | Not | 178 | 565 |
| | | measurable | | |
| Voids after thermocompression bonding | C | C | C | C |

As shown in Table 1 and Table 2, the laminated films (film-form adhesives) of Examples 1 to 9 showed suppressed voids after thermocompression bonding compared to the laminated films (film-form adhesives) of Comparative Examples 1 to 4. From the above, it was confirmed that the thermosetting adhesive composition of the present disclosure can suppress the occurrence of voids at the interface between the film-form adhesive and a member when a die bonding step is performed using the film-form adhesive made of the thermosetting adhesive composition.

### REFERENCE SIGNS LIST

1 . . . base film, 3 . . . adhesive layer, 3c, 3p . . . adhesive piece, 5, 5p . . . cover film, 10 . . . laminated film, 12 . . . printed circuit board, 15 . . . FPC board, 15a . . . tip portion, 20 . . . punched product, 50A, 50B . . . module (connection body), C . . . semiconductor chip, W1, W2 . . . wire.

1. A thermosetting adhesive composition comprising: a thermosetting resin; a thermoplastic resin; an inorganic filler; and a photocleavable compound that cleaves upon irradiation with ultraviolet rays to generate an amine compound,
wherein the thermosetting resin is a resin that cures by being heated in the presence of the amine compound,
after the thermosetting adhesive composition is irradiated with ultraviolet rays under conditions of an illuminance of 80 mW/cm² and an integrated light quantity of 600 mJ/cm², a shear viscosity of the thermosetting adhesive composition at 75° C. is from 100 to 6,000 Pa·s, and
after the thermosetting adhesive composition is irradiated with ultraviolet rays under conditions of an illuminance of 80 mW/cm² and an integrated light quantity of 600 mJ/cm² and further heated at 75° C. for 3 hours, a storage modulus of the thermosetting adhesive composition at 35° C. is from 100 to 4,000 MPa.

2. The thermosetting adhesive composition according to claim 1, wherein after the thermosetting adhesive composition is irradiated with ultraviolet rays under conditions of an illuminance of 80 mW/cm² and an integrated light quantity of 600 mJ/cm² and further heated at 75° C. for 3 hours, a storage modulus of the thermosetting adhesive composition at 75° C. is 10 MPa or more.

3. The thermosetting adhesive composition according to claim 1, wherein a content of the thermoplastic resin is from 5 to 35% by mass, based on a total amount of the thermosetting adhesive composition.

4. The thermosetting adhesive composition according to claim 1, wherein a content of the inorganic filler is 45% by mass or less, based on a total amount of the thermosetting adhesive composition.

5. The thermosetting adhesive composition according to claim 1, wherein the photocleavable compound is a compound having an α-aminoacetophenone skeleton.

6. The thermosetting adhesive composition according to claim 1, wherein a reaction rate calculated by substituting a calorific value C1 and a calorific value C2, which are respectively obtained from a DSC curve obtained by differential scanning calorimetry at a heating rate of 10° C./min in a temperature range of 50 to 200° C., into the following formula is 45% or more:
Reaction rate (%)=(C1−C2)/C1×100
where C1 represents the calorific value for which a measurement target is a resin composition after the thermosetting adhesive composition has been irradiated with ultraviolet rays under conditions of an illuminance of 80 mW/cm² and an integrated light quantity of 600 mJ/cm², and
C2 represents the calorific value, for which a measurement target is a resin composition after the thermosetting adhesive composition has been irradiated with ultraviolet rays under conditions of an illuminance of 80 mW/cm² and an integrated light quantity of 600 mJ/cm² and further heated at 75° C. for 3 hours.

7. The thermosetting adhesive composition according to claim 1, wherein a glass transition temperature of the thermoplastic resin is from −50 to 20° C.

8. An ultraviolet-irradiated product of a thermosetting adhesive composition, obtained by irradiating the thermosetting adhesive composition according to claim 1 with ultraviolet rays,
wherein the product comprising: the thermosetting resin; the thermoplastic resin; the inorganic filler; and the amine compound,
a shear viscosity of the ultraviolet-irradiated product at 75° C. is from 100 to 6,000 Pa·s, and
after being heated at 75° C. for 3 hours, a storage modulus of the ultraviolet-irradiated product at 35° C. is from 100 to 4,000 MPa.

9. A laminated film comprising:
a base film; and
an adhesive layer provided on a surface of the base film,
wherein the adhesive layer is formed of the thermosetting adhesive composition according to claim 1.

10. A method for producing a connection body, the method comprising, in this order:
(A) providing a laminate comprising a first circuit member, a second circuit member, and an adhesive layer disposed between the first circuit member and the second circuit member;
(B) heating the laminate at 65 to 85° C. for 30 to 240 minutes; and
(C) wire bonding the first circuit member and the second circuit member,
wherein the adhesive layer is formed of the thermosetting adhesive composition according to claim 1, and
the method further comprises irradiating the adhesive layer with ultraviolet rays before step (B).

11. The method according to claim 10,
wherein the first circuit member is one selected from the group consisting of a printed circuit board and a semiconductor chip, and the second circuit member is a flexible printed circuit board.

12. A method for producing a connection body, the method comprising, in this order:
(A) providing a laminate comprising a first circuit member, a second circuit member, and an adhesive layer disposed between the first circuit member and the second circuit member;
(B) heating the laminate at 65 to 85° C. for 30 to 240 minutes; and
(C) wire bonding the first circuit member and the second circuit member,
wherein the adhesive layer is formed of the ultraviolet-irradiated product of the thermosetting adhesive composition according to claim 8.

13. The method according to claim 12, wherein the first circuit member is one selected from the group consisting of a printed circuit board and a semiconductor chip, and the second circuit member is a flexible printed circuit board.

14. A connection body comprising:
a first circuit member;
a second circuit member; and
an adhesive layer disposed between the first circuit member and the second circuit member,
wherein the adhesive layer is formed of a cured product of the thermosetting adhesive composition according to claim 1.

15. A connection body comprising:
a first circuit member;
a second circuit member; and
an adhesive layer disposed between the first circuit member and the second circuit member,
wherein the adhesive layer is formed of a cured product of the ultraviolet-irradiated product of the thermosetting adhesive composition according to claim 8.

16. The thermosetting adhesive composition according to claim 1, wherein the thermosetting resin comprises an epoxy resin and a phenolic resin.

17. The thermosetting adhesive composition according to claim 16, wherein the epoxy resin comprises an epoxy resin that is liquid at 25° C. and an epoxy resin that is solid at 25° C.
